(19) United States
(12) Patent Application Publication
(10) Pub. No.: US 2024/0164063 A1
(43) Pub. Date: May 16, 2024

(54) AXIALLY ARRANGED COMMUNICATION AND THERMAL INTERCONNECTS FOR FOLDABLE ELECTRONIC DEVICES

(71) Applicant: Intel Corporation, Santa Clara, CA (US)

(72) Inventors: Samarth Alva, Bangalore (IN); Prakash Kurma Raju, Bangalore (IN); Shivaraju Neerati, Bhupalpalle (IN); Navneet Singh, Bangalore (IN); Ravishankar Srikanth, Bengaluru (IN)

(21) Appl. No.: 18/394,829

(22) Filed: Dec. 22, 2023

(51) Int. Cl. H05K 7/20; G06F 1/16; H05K 5/02

(52) U.S. Cl. CPC H05K 7/20509; G06F 1/1681; G06F 1/1683; H05K 5/0226; H05K 5/0247

(57) ABSTRACT

An electronic device or a component thereof is described, which may include communication and/or thermal interconnects. The device may include hingedly coupled portions, where the interconnects are axially arranged (e.g., coincident) with respect to a hinge axis of the foldable electronic device.

### TECHNICAL FIELD

The disclosure described herein generally relates to communication and/or thermal interconnects for hingeable electronic devices, including interconnects axially arranged (e.g., coincident) with respect to a hinge axis of the foldable electronic device.

### BACKGROUND

Foldable electronic devices such as clamshell and notebooks require the passage of cables between foldable portions, such as between the base and lid. These cables may carry signals and power for the display and other hardware such as cameras, microphones, speakers, etc. on the lid. Conventional systems generally have a limited angular range (e.g., 135°) with respect to the foldable components. Some systems may have an included angular range, but require the routing of interconnects parallel to the hinge mandrel which disadvantageously increases the overall size of the hinge due to the increase size of the barrel housing the interconnects and mandrel. Other conventional systems include extended interconnects that have increased lengths to accommodate larger angular ranges. However, such systems require additional tension devices to roll and unroll the interconnects during opening and closing of the foldable portions, which increase the size of the hinge system and reduce the available internal footprint of the device.

### BRIEF DESCRIPTION OF THE DRAWINGS/FIGURES

The accompanying drawings, which are incorporated herein and form a part of the specification, illustrate the present disclosure and, together with the description, further serve to explain the principles and to enable a person skilled in the pertinent art to make and use the techniques discussed herein.

In the drawings, like reference characters generally refer to the same parts throughout the different views. The drawings are not necessarily to scale, emphasis instead generally being placed upon illustrating the principles of the disclosure. In the following description, reference is made to the following drawings, in which:

FIG. 1 illustrates a foldable electronic device according to the disclosure in an open state.

FIG. 2 illustrates a foldable electronic device according to the disclosure in an open state.

FIG. 3A illustrates a partial view of a base of an electronic device according to the disclosure, with the lid omitted for clarity.

FIG. 3B is a cross-sectional, partial view of the base of an electronic device according to FIG. 3A.

FIG. 4 illustrates a partial view of a lid of an electronic device according to the disclosure, with the base omitted for clarity.

FIG. 5 is an enlarged, partial view of the lid of FIG. 4.

FIG. 6 is a cross-sectional, partial view of the lid of FIG. 4.

FIG. 7A is a cross-sectional, partial view of a lid of an electronic device according to the disclosure.

FIG. 7B is a schematic, partial, cross-sectional view of a lid of an electronic device according to the disclosure.

FIG. 8A is a cross-sectional, partial view of an electronic device according to the disclosure with the lid in a closed position.

FIG. 8B is an enlarged, cross-sectional, partial view of the electronic device of FIG. 8A.

FIG. 9A is a cross-sectional, partial view of an electronic device according to the disclosure with the lid in a closed position.

FIG. 9B is a cross-sectional, partial view of the electronic device according to FIG. 9A with the lid in an open (e.g., 90°) position.

FIG. 9C is a cross-sectional, partial view of the electronic device according to FIG. 9A with the lid in an open (e.g., 180°) position.

FIG. 10A is a schematic, cross-sectional, partial view of an electronic device according to the disclosure with the lid in a closed position.

FIG. 10B is a schematic, cross-sectional, partial view of the electronic device according to FIG. 10A with the lid in an open (e.g., 180°) position.

FIG. 11 illustrates a foldable electronic device according to the disclosure in an open state.

FIG. 12 illustrates a schematic view of a foldable electronic device according to the disclosure.

FIG. 13 illustrates a schematic view of a foldable electronic device according to the disclosure.

The present disclosure will be described with reference to the accompanying drawings. The drawing in which an element first appears is typically indicated by the leftmost digit(s) in the corresponding reference number.

### DETAILED DESCRIPTION

The following detailed description refers to the accompanying drawings that show, by way of illustration, exemplary details in which the disclosure may be practiced. In the following description, numerous specific details are set forth in order to provide a thorough understanding of the present disclosure. However, it will be apparent to those skilled in the art that the various designs, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring the disclosure.

Foldable electronic devices include interconnects (e.g., interconnect 602) for data, power, and/or thermal transmissions between the various components that are movable with respect to each other (e.g., between a base (chassis) and the lid (e.g., display) portion). A portion or the entirety of the interconnect may be flexible, rigid, or semi-rigid/flexible. Additionally, or alternatively, the flexible or semi-flexible conductor may have two or more portions that include different degrees of flexibility/stiffness.

The interconnects span the foldable portion/area between the movable portions of electronic devices and are configured to withstand mechanical stress due to the repeated opening and closing of the electronic device over its lifespan. The interconnect(s) may be routed within one or more hinges coupling the movable components together and/or may be routed independent of the hinge(s). In one or more aspects, all of the interconnects may be routed independent (e.g. outside of) the hinge(s), all of the interconnects may be routed within (e.g., at least partially inside of) the hinge(s), or one or more interconnects may be routed independent of one or more hinges while one or more other interconnects may be routed within the hinge(s).

As described above, the (flexible) interconnects may be cables or other conductor(s), such as those configured for data signal transmission and/or power transmission. The interconnects may be flexible flat cable (FFC), flexible printed circuits (FPC), Flexible Flat Printed Circuits (FFPC), coaxial cables, solid-wire cables, stranded-wire cables, single-conductor cables, ribbon cables, or the like. The interconnects may be made of, or include, one or more metals, such as copper, aluminum, gold, etc. and/or a composite thereof. Additionally, or alternatively, the interconnect(s) may be configured for optical transmissions, such as fiber optic cables.

Additionally, or alternatively, the interconnect(s) may be thermal conductors, such as heat spreaders, configured to transfer (e.g., conduct) heat from one area to another. For example, a flexible heat spreader may be configured as a thermal cooling device to facilitate the removal of thermal energy from one or more heat sources. In this example, a first portion of the heat spreader may be thermally connected to a heat source and a second portion of the heat spreader may be a passive cooling device, and/or thermally connected to one or more passive cooling devices. Additionally, or alternatively, the second (or additional) portion may be an active cooling device (e.g., fan) and/or connected to an active cooling device. The thermal conductor(s) may be made of metal, a metal composite, graphite, and/or other material(s) that conduct heat. The thermal conductor may be in the form of a sheet, such as a graphite sheet.

It is noted that although described herein with respect to a rotating (i.e. foldable) electronic device such as a laptop computer, this is a non-limiting and illustrative application. The electronic device described in further detail herein may be implemented in accordance with any suitable type of device. In one or more aspects, the interconnect may have a thickness (h) of, for example, 0.15 mm; a bend radius (r) of 1.0 mm to 1.5 mm; and/or a bend radius-to-thickness ratio (r/h) of at least 10. Additionally, or alternatively, the flexibility of the interconnect (at least at the bend area) may be that of a polyimide sheet of 0.15 mm thickness.

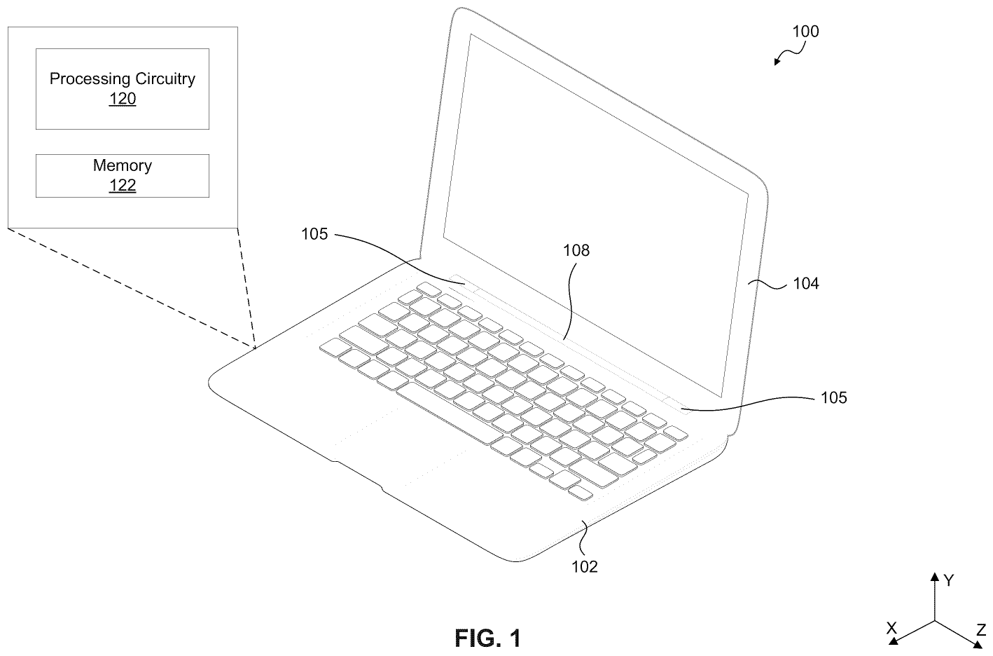

FIG. 1 illustrate illustrates a foldable electronic device 100 according to the disclosure, in an open state. The electronic device 100 may comprise a laptop computer, although the use of the interconnects as discussed herein may be implemented in any suitable type of electronic device. The electronic device 100 may include processing circuitry 120 configured to perform one or more processing operations and memory 122. The memory 122 may store data and/or instructions. The processing circuitry 120 may execute one or more instructions (e.g., stored in memory 122) to perform one or more operations of the computing device 100.

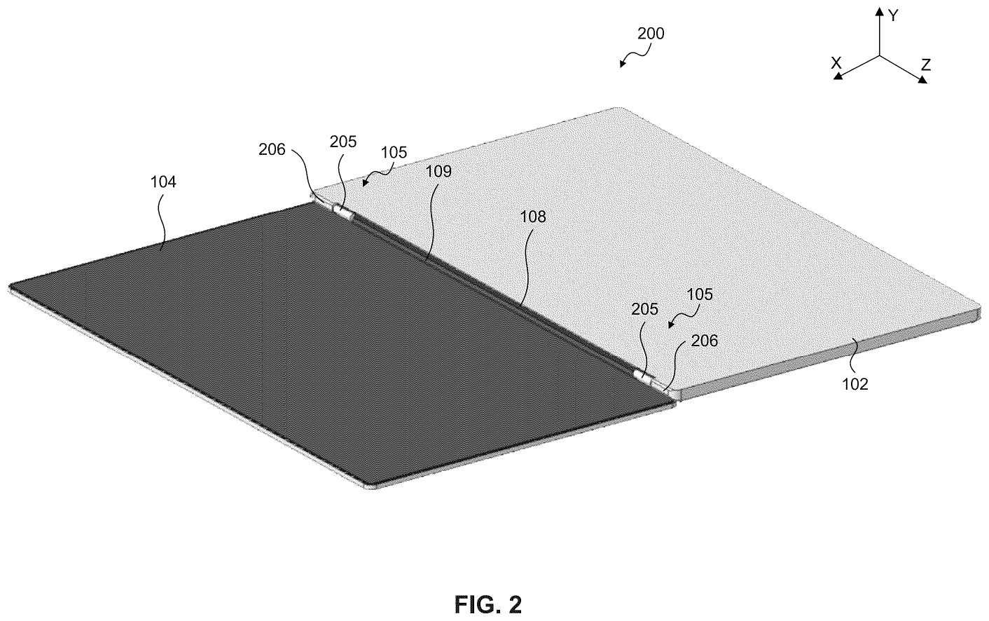

The electronic device 100 may include various portions that are movable with respect to each other. For example, the electronic device 100 may include a base or chassis portion 102 that is movably (e.g., rotatably) coupled to a lid portion 104. The electronic device 100 may comprise one or more hinge structures (hinges) 105 configured to hingeable couple the base 102 to the lid 104. The hinge 105 may be comprised of two or more hinge portions that hingeably couple together, where a first hinge portion is connected to the base 102 and a second hinge portion is connected to lid 104 (see FIG. 2).

One or more of the portions 102 and 104 may include one or more input/output (I/O) devices, such as one or more displays (e.g., touchscreen display), speaker(s), keyboard(s), microphone(s), camera(s), touchpad(s), biometric and/or other sensors, I/O port(s), and/or other interfaces. In the illustrated example, the base 102 includes a keyboard and touchpad, while the lid 104 includes a display. However, the disclosure is not limited thereto and other device configurations or possible, such as where both portions 102 and 104 include touchscreen displays, such as a foldable mobile communication device.

FIG. 2 illustrates a foldable electronic device 200 according to the disclosure, in an open state. The electronic device 200 of FIG. 2 maybe similar to the device 100. As shown in FIG. 2, the electronic device 200 is opened with a rotation at 180°. The electronic device 200, like electronic device 100, may include a base 102 and lid 104, which are rotatably coupled together by hinges 105. The hinges 105 may be the same or different. In the illustrated example, the hinge(s) 105 may include a first rotatable engagement mechanism or portion 205 and a second rotatable engagement mechanism or portion 206, where each rotatable engagement mechanism or portion is configured to engage and couple to the other to form a rotatable coupling. The rotatable engagement mechanism or portion 205 may be further coupled to the lid 104 while the rotatable engagement mechanism or portion 206 is further coupled to the base 102. Via the rotatable engagement mechanism or portion 205 and the rotatable engagement mechanism or portion 206 forming hinge 105, the base 102 and 104 are rotatably coupled together such that the base 102 and lid 104 are rotatably moveable with respect to each other. The electronic device 200 may further include cover 108 that is configured to extend from the base 102 and cover 108 that is configured to extend from the lid 104. The covers 108 and/or 109 may extend into a gap present between the hingedly connected base 102 and lid 104 to cover or otherwise hide the appearance of the gap and/or be support one or more interconnects extending between the base 102 and the lid 104. As will be appreciated, the degree of hinged rotation of the electronic device 200 is not limited to at 180° and the device may have another maximum degree of rotation, such as at 135° or at 360°.

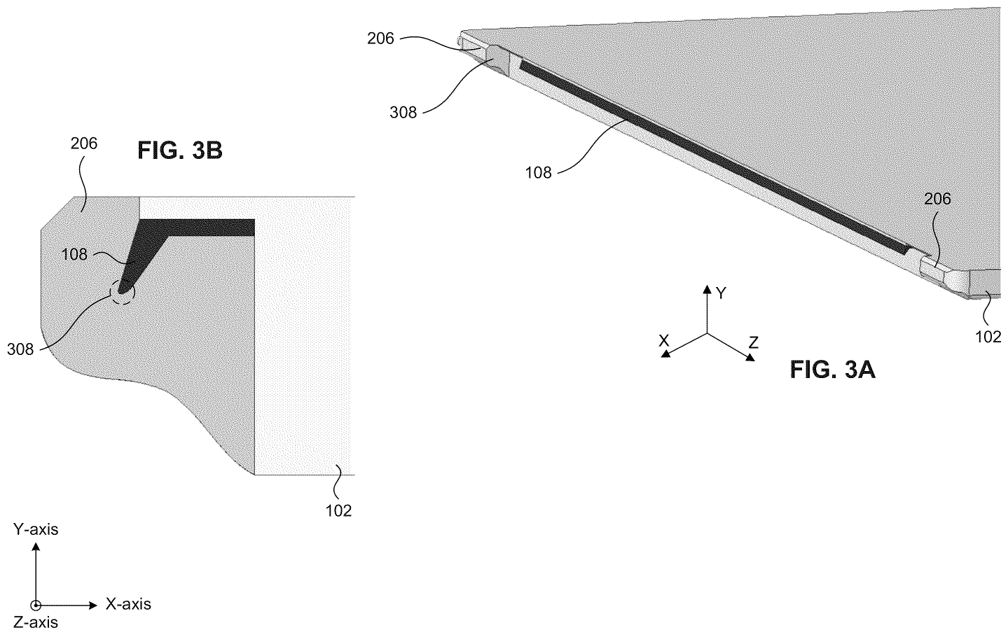

FIG. 3A illustrates a partial view of the base 102 of electronic device 200 according to the disclosure, with the lid 104 omitted for clarity. In this view, the hinge axis 308 is shown (blue circle). The hinge axis 308 defines the axis of rotation of the hinges 105. For example, hinge portion 205 rotates above the hinge axis 308 when rotating with respect to the hinge portion 206. The base 102 may house one or more electronic components (e.g., processors, circuits, etc.) that are couplable to components in the lid 104. In this example, the base 102 may house or at least partially house at least a portion of the interconnect(s) configured to couple the base 102 and lid 104 together.

FIG. 3B is a cross-sectional, partial view of the base 102 of the electronic device 200 according to FIG. 3A. The cross-sectional view again shows the hinge axis 308, and the extension of the cover 108. In this example, the cover 108 may extend to or substantially adjacent to the hinge axis 308.

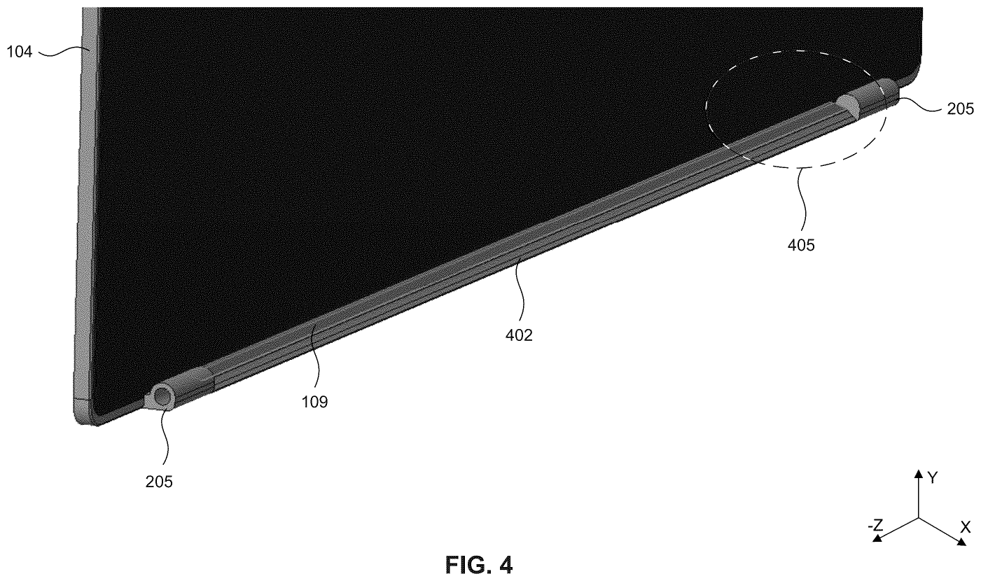

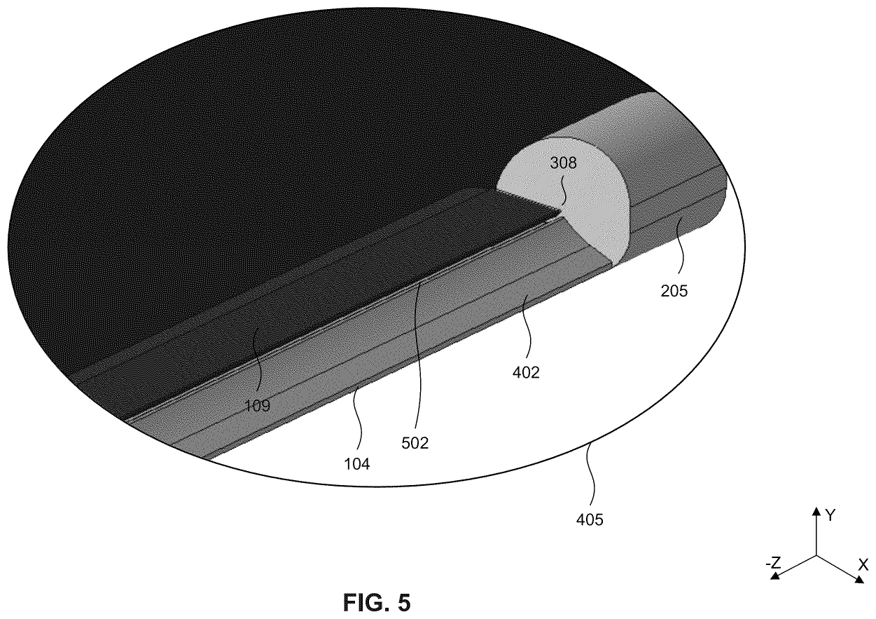

FIG. 4 illustrates a partial view of the lid 104 of electronic device 200 according to the disclosure, with the base 102 omitted for clarity. The hinge portion 205 shares the same hinge axis 308, which is shown in the enlarged detail view of FIG. 5. Like the base 102, the lid 104 may house or at least partially house at least a portion of the interconnect(s) configured to couple the base 102 and lid 104 together. The lid 104 may include a support surface 402 configured to support one or more interconnects entering/exiting an interior housing portion of the lid 104.

FIG. 5 is an enlarged, partial view of the lid of FIG. 4. FIG. 5 shows enlarged portion 405 of FIG. 4. As is illustrated in FIG. 5, a gap 502 may be formed between the support surface 402 and the cover 109 (green portion in FIG. 4, shown in greyscale in FIG. 5). One or more of the interconnects may pass through this gap 502 when entering/exiting the interior housing portion of the 104. The support surface 402 and/or an opposing surface of the cover 109 may support one or more interconnects. Additionally, or alternatively, one or more interconnects may be fixed (at least partially) to the support surface 402 and/or cover 109. Additionally, or alternatively, the interconnect(s) may be fixed (at least partially) to the cover 108 of the base 102.

As discussed above, the hinge portion 205 shares the same hinge axis 308 at the hinge portion 206. In this example, the hinge axis 308 (teal circle) coincides with the gap 502 and/or is substantially adjacent thereto. In this configuration, and as explained in more detail below, one or more interconnects extending from the lid 104 via the gap 502 will exit the lid 104 at a location that coincides (e.g., is coincident and/or is axially arranged) with the hinge axis 308.

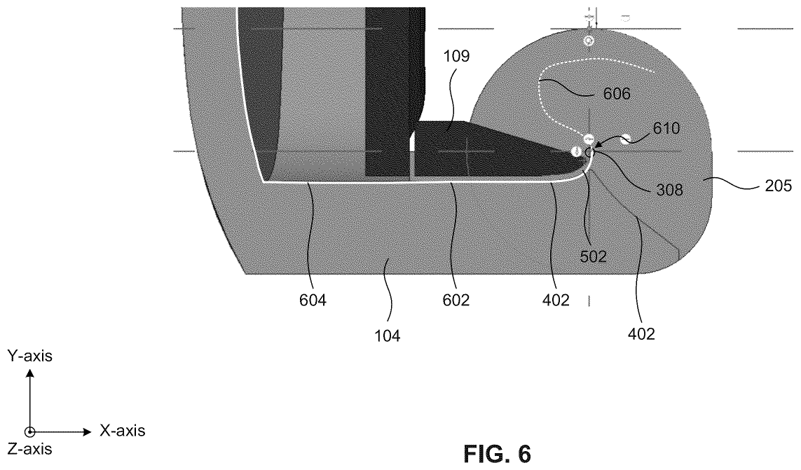

FIG. 6 is a cross-sectional, partial view of the lid 104 of FIGS. 4 and 5. As further illustrated, the gap 502 is formed between support surface 402 of the cover 109. In this gap 502, interconnect 602 is housed. The interconnect 602 may be at least partially fixed to the surface 402 and/or the cover 108. In this example, the lid structure is shown in grayscale, with the interconnect shown by a solid and broken/dashed line. The interconnect 602 is shown with two portions 604 (solid line) and 606 (broken/dashed) (white) line. In this example, the portion 604 is a fixed portion and the portion 602 is a free portion of the interconnect 602. In this example, the free portion 606 is not fixed to the lid 104 and has freedom movement (e.g., during rotation of the 104 with respect to the base 102 via the hinge 105.

The delineation 610 between the fixed portion 604 and the free portion 606 may coincide with the hinge axis 308. In this example, the opening of the gap 502 may additionally coincide with the delineation 610 and/or the hinge axis 308. The free portion 606 is illustrated as a curved portion extending upward (y-direction), but it should be understood that the position of the free portion 606 is only an example position as the free portion 606 is free to move about the electronic device 200. For example, the free portion 606 may rest on the surface 402 located outside of the gap 502.

Advantageously, with the coincidence of the hinge axis 308 and the delineation 610 between the fixed portion 604 and the free portion 606, the mechanical strain on the interconnect 602 is reduced while allowing for the interconnect 602 to have a reduced length as compared to convention techniques that require additional rollers and/or tensioning mechanisms for manipulating and controlling slack formed in the interconnect during rotation. The electronic device 200 provide a further advantage in that a portion (e.g. fixed portion 604) of the interconnected 602 may have increased stiffness, thereby increasing the mechanical strength and robustness. In one or more aspects, the interconnect 602 may include a coating, such as a silicone-based coating, a coating providing a reduced coefficient of friction (e.g., Polytetrafluoroethylene (PTFE)), and/or one or more other coatings (e.g., polyethylene terephthalate (PET)) in at least the bend region (e.g., portions adjacent to the delineation 610) to increase the resilience of the interconnect 602 and further improve the robustness and reliability of the electronic device 200. With the omission of rollers and/or tensioning mechanisms, the electronic device 200 increases the available footprint within the computing device 200 for one or more other components, such as circuitry, batteries, etc.

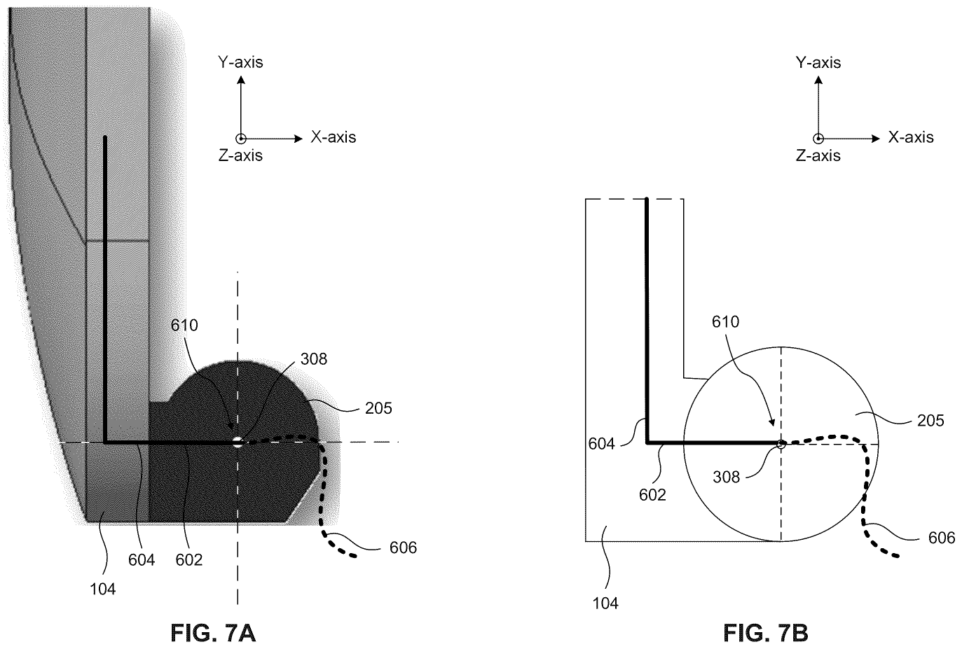

FIG. 7A is a cross-sectional, partial view of lid 104 of electronic device 200 according to the disclosure. The lid 104 is similar to the lid illustrated in FIG. 6, and the cover 109 is omitted for clarity. In this example, the interconnect 602 is illustrated as a black solid (604) and dashed/broken (606) line. Again, the portion 604 of the interconnect 602 corresponding to the fixed portion and the portion 606 corresponding to the free portion of the interconnect 602.

FIG. 7B is a schematic, partial, cross-sectional view of lid 104 of electronic device 200 according to the disclosure. FIG. 7B is similar to the illustration as shown in FIG. 7A, but shown in a schematic illustrate for additional clarity.

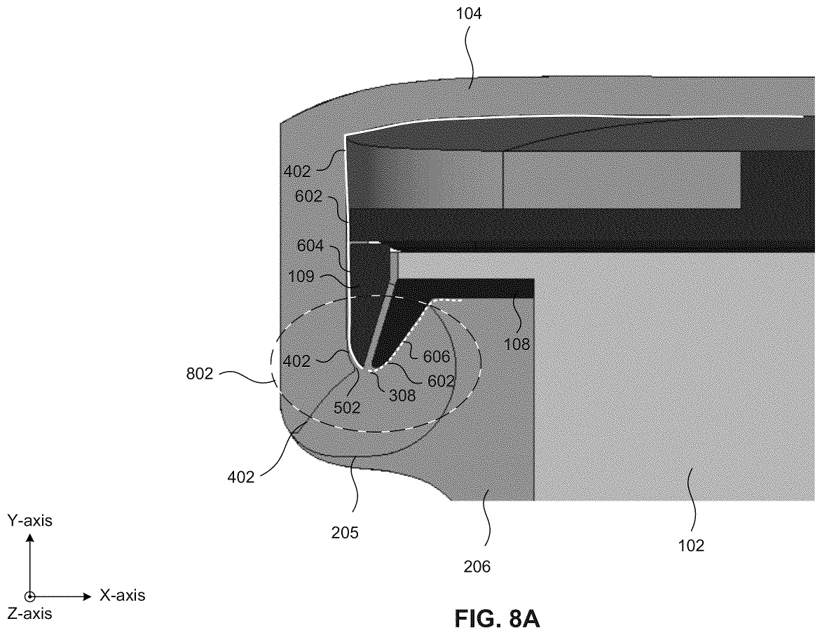

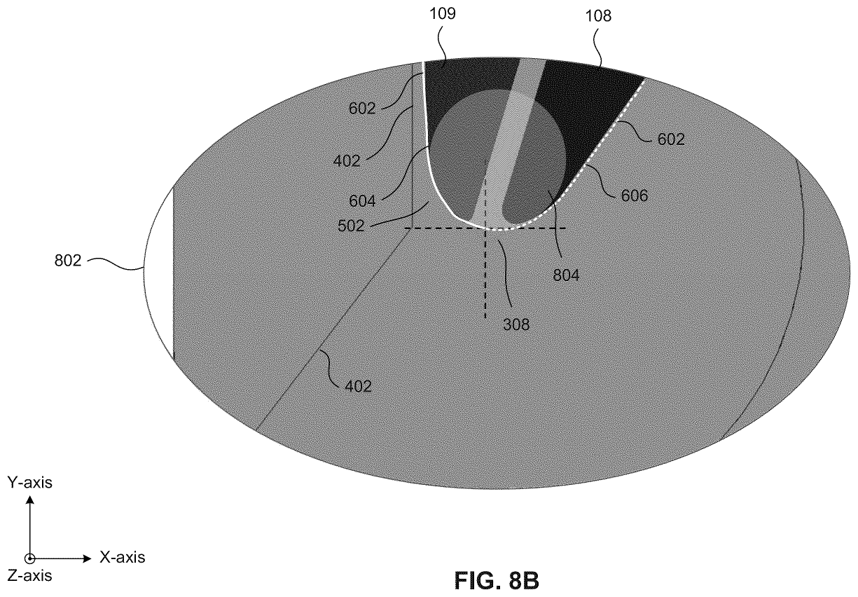

FIG. 8A is a cross-sectional, partial view of an electronic device 200 according to the disclosure, with the lid 104 in a closed position (e.g., 0°). As shown, interconnect 602 is housed within the lid 104, and extends between cover 109 and the support surface 402 of the lid 104. The interconnect 602 may be housed within the gap 502 formed between the cover 109 and the support surface 402. Similar to the above examples, the interconnect has a first portion 604 housed within the lid 402, which may be the fixed portion 604. The interconnected 602 may have a free portion 606, where the delineation between the portions 604 and 606 is positioned at the hinge axis 308. That is, the electronic device 200 is configured such that the interconnect is fixedly secured to the lid 104 until the interconnect 602 reaches the hinge axis 308. At this coinciding point, the interconnect 602 is no longer fixed and has freedom of movement to facilitate the rotational movement of the lid 104 with respect to the base 102, which may include, for example, 180° or more of movement.

As further illustrated, the gap 502 is formed between support surface 402 of the cover 109. In this gap 502, interconnect 602 is housed. The interconnect 602 may be at least partially fixed to the surface 402 and/or the cover 108. In this example, the lid structure is shown in grayscale, with the interconnect shown by a solid and broken/dashed (white) line. The interconnect 602 is shown with two portions 604 (solid line) and 606 (broken/dashed) line. In this example, the portion 604 is a fixed portion and the portion 602 is a free portion of the interconnect 602. In this example, the free portion 606 is not fixed to the lid 104 and has freedom movement (e.g., during rotation of the 104 with respect to the base 102 via the hinge 105. In this example, the free portion 606 is illustrated as following the surface of the cover 108, but it should be understood that the position of the free portion 606 is only an example position as the free portion 606 is free to move about the electronic device 200.

FIG. 8A includes reference to portion 802, which is enlarged for added clarity and shown in FIG. 8B. In FIG. 8B, the bend region 804 (e.g., portions adjacent to the hinge axis 308) is shown by a light blue circle that partially encompasses the covers 108 and 109, and is adjacent to the hinge axis 208, which is shown as a blue, unshaded circle. The axis 308 is further illustrated by dashed crosshairs. In the bend region 804, the interconnect 602 may bend to form, for example, a 35° bend. Additionally, or alternatively, the bend region 804 may be tangential to the hinge axis 308 (as illustrated by the crosshairs), and have a radius of, for example, 1 mm to 1.5 mm (e.g., R1 to R1.5).

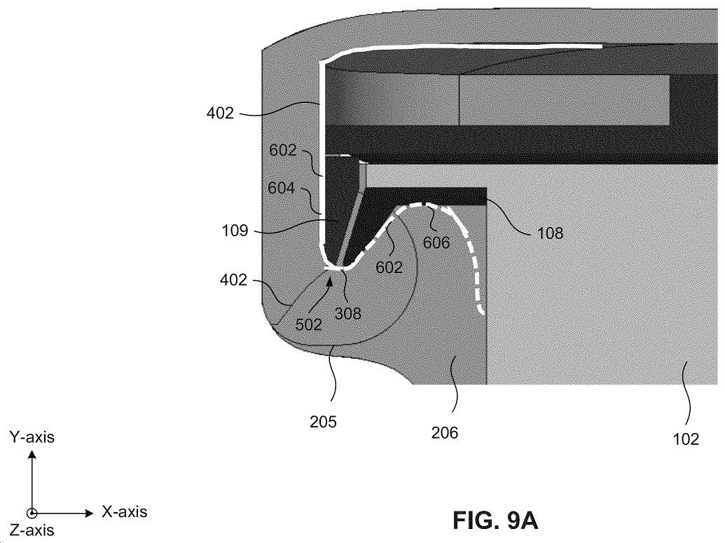

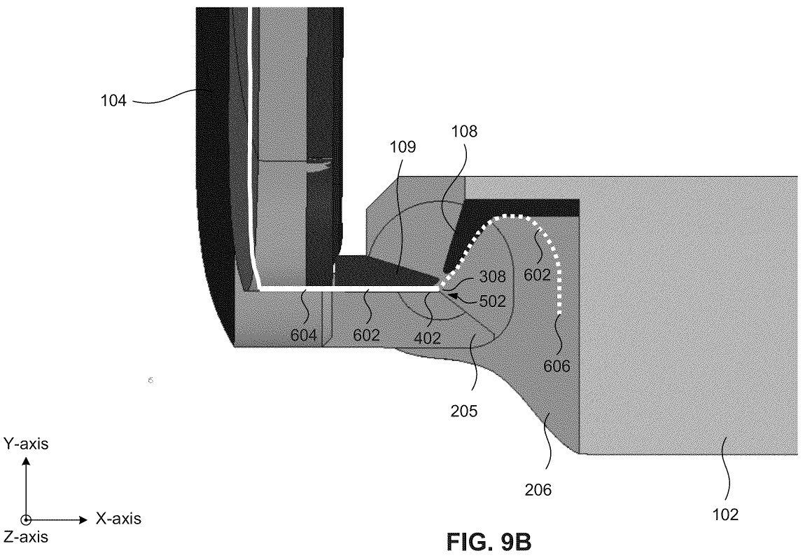

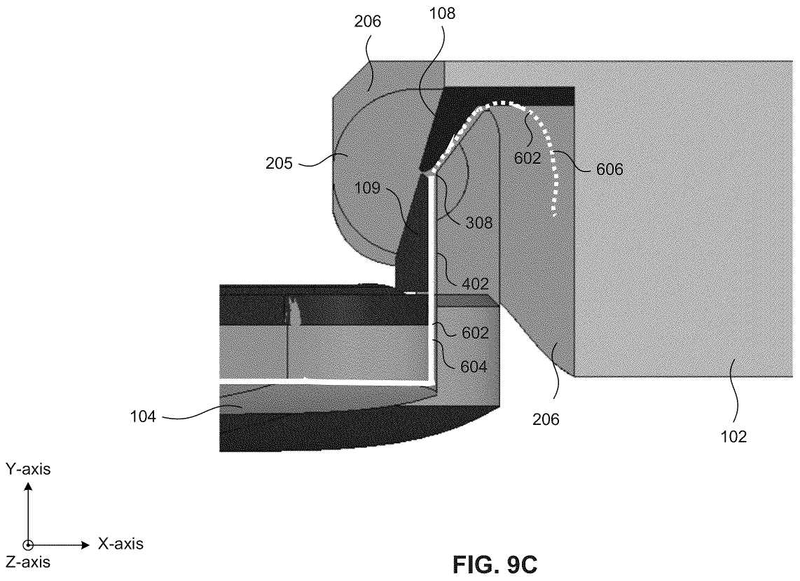

FIG. 9A is a cross-sectional, partial view of an electronic device 200 according to the disclosure, with the lid 104 in a closed position (e.g., 0°). FIG. 9A is similar to FIG. 8A, but shows the free portion 606 of the interconnect in a different position.

FIG. 9B is a cross-sectional, partial view of electronic device 200 of FIG. 9A, but with the lid 104 in an open position (e.g., 90°). FIG. 9C is a cross-sectional, partial view of electronic device 200 of FIGS. 9A and 9B, but with the lid 104 in a further open position (e.g., 180°).

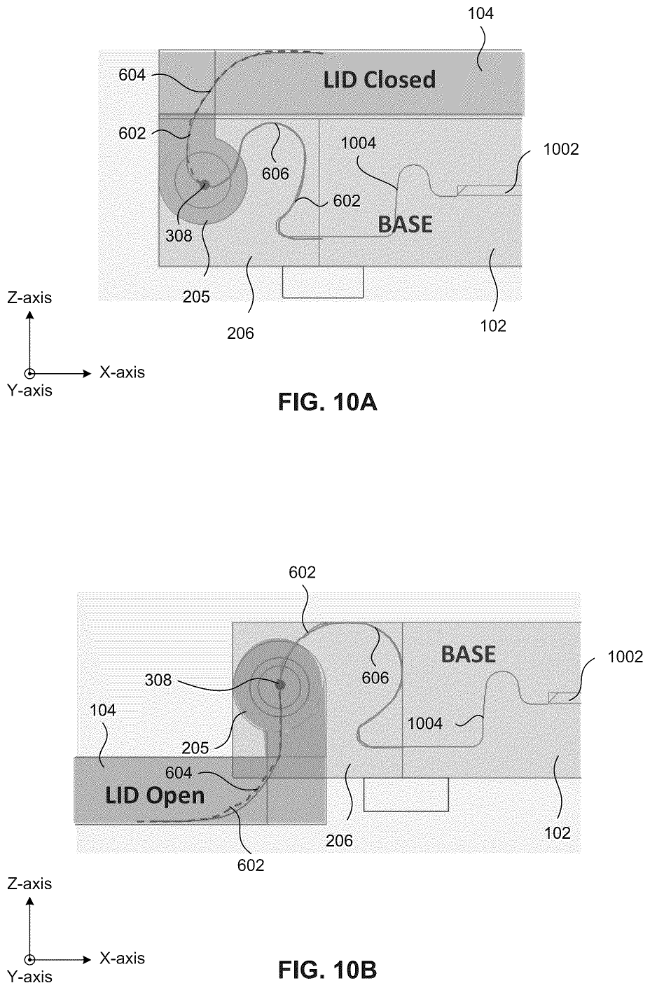

FIG. 10A is a schematic, cross-sectional, partial view of electronic device 200 according to the disclosure with the lid 104 in a closed position. This example is similar to that of FIG. 9A, but is shown schematically for additional clarity. FIG. 10B is a schematic, cross-sectional, partial view of electronic device 200 according to FIG. 10A with the lid in an open (e.g., 180°) position. This example is similar to that of FIG. 9C, but is shown schematically for additional clarity. In these examples, the interconnect 602 is again shown with fixed portion 604 (red dashed line) and free portion 606 (blue solid line). The interconnect 602 may be further connected to one or components, such as a further interconnect 1004 that connected to component 1002, such as one or more electronic components (e.g. processor).

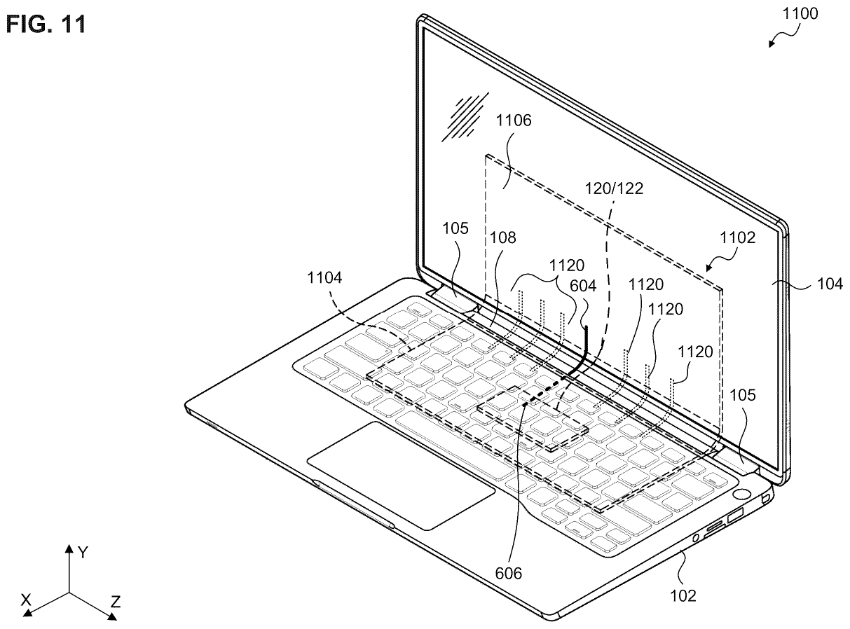

FIG. 11 illustrates a foldable electronic device 1100 according to the disclosure in an open state. The electronic device 1100 may be similar to electronic device 100 and/or electronic device 200, and be foldable about axis 308. The electronic device 1100 may include various portions that are movable with respect to each other. For example, the electronic device 1100 may include a base or chassis portion 102 that is movably (e.g., rotatably) coupled to a lid portion 104. The electronic device 100 may comprise one or more hinge structures (hinges) 105 configured to hingeable couple the base 102 to the lid 104. The electronic device 1100 may include one or more interconnects 602, which may have a fixed portion 604 and free portion 606. In this example, the fixed portion 604 is housed (at least partially) within the lid 104 while the free portion 606 is housed (at least partially) within the base 102. However, in other aspects of electronic device 1100 (and/or electronic devices 100 and/or 200), the fixed portion may be located in the base 102 while the free portion is located in the lid 104. The interconnect 602 may couple electronics (e.g., processing circuitry 120 and/or memory 122) in the base 102 to one or more components (e.g., display) in the lid 104.

The electronic device 1100 may additionally or alternatively include one or more thermal conductors 1102. The thermal conductor(s) 1102 may be a heat spreader, such as a graphite sheet. The thermal conductor(s) 1102 may be configured to transfer (e.g., conduct) heat from one area to another. For example, a flexible thermal conductor 1102 may be configured as a thermal cooling device to facilitate the removal of thermal energy from one or more heat sources (e.g., processing circuitry 120 and/or memory 122) and dissipate the thermal energy in another location (e.g., in the lid 104). In this example, a first portion 1104 of the thermal conductor 1102 may be thermally connected to a heat source and a second portion 1106 of the thermal conductor 1102 may be a passive cooling device, and/or thermally connected to one or more passive cooling devices, in the lid 104. For example, the second portion 1106 may be thermally coupled to the housing of the lid 104 so that thermal energy transferred to the second portion 1106 may be dissipated in the housing of the lid 104. Additionally, or alternatively, electronic device 1100 may include one or more active cooling devices (e.g., fan), and the first portion 1104 and/or second portion 1106 may be thermally coupled to the active cooling device(s). The thermal conductor(s) may be made of metal, a metal composite, graphite, and/or other material(s) that conduct heat. The thermal conductor may be in the form of a sheet, such as a graphite sheet.

Thermal conductor(s) 1102 may be configured and routed similarly as the interconnect(s) according to one or more aspects. For example, the thermal conductor 1102 may have a fixed portion and a free portion, where the delineation between the fixed and free portions coincides with the hinge axis 308.

Additionally, or alternatively, the thermal conductor(s) 1102 may include one or more elongated slits 1120 that extend between the base or chassis portion 102 and the lid portion 104 of the device 1100. The elongated slits 1120 may be similarly dimensioned, or one or more elongated slits 1120 may have different dimensions than one or more other elongated slits 1120. The number of elongated slits 1120 is not limited to the illustrated example, and the electronic device may include more or less elongated slits 1120. The elongated slits 1120 may be similarly or differently spaced and/or positioned with respect to other elongated slits 1120. One or more of the elongated slits 1120 may accommodate one or more interconnects 602 therein. For example, the interconnect(s) 602 may be positioned so as to coincidence with respective positions of the elongated slits 1120. In some aspects, one or more interconnects 602 may be accommodated within one or more of the elongated slits 1120, while other interconnects 602 are positioned outside of the elongated slit(s) 1120. The slit(s) 1120 maybe positioned or otherwise localized at the bend area (e.g., bend region 804 and/or an area coinciding with and/or adjacent to the hinge axis 308). The slit(s) 1120 advantageously increase the pliability and/or flexibility of the thermal conductor 1102 (e.g., graphite and/or other thermally conductive sheet) and/or reduce or eliminate wrinkles, kinks, and/or other mechanical stress formations that may result during bending, which may be more prevalent as the width (e.g., in the axial direction, z-direction) of the thermal conductor 1102 increases. These advantages improve the reliability and/or robustness (e.g., mechanical reliability) of the thermal conductor 1102. Additionally, or alternatively, the thermal conductor 1102 may include one or more coatings on or more areas (e.g., bend area), such as a silicone-based coating, a coating providing a reduced coefficient of friction (e.g., Polytetrafluoroethylene (PTFE)), and/or one or more other coatings (e.g., polyethylene terephthalate (PET)). For example, the bend region can include a PTFE coating of, for example, 0.05 mm to further enhance the robustness of the thermal conductor 1102. The coating(s) may be applied to one or more portions/regions (or the entirety (e.g., entire surface(s)) of the thermal conductor 1102. As a further advantage, the thermal performance of the thermal conductor 1102 is not impacted by the inclusion of the slit(s) 1102 and coating(s).

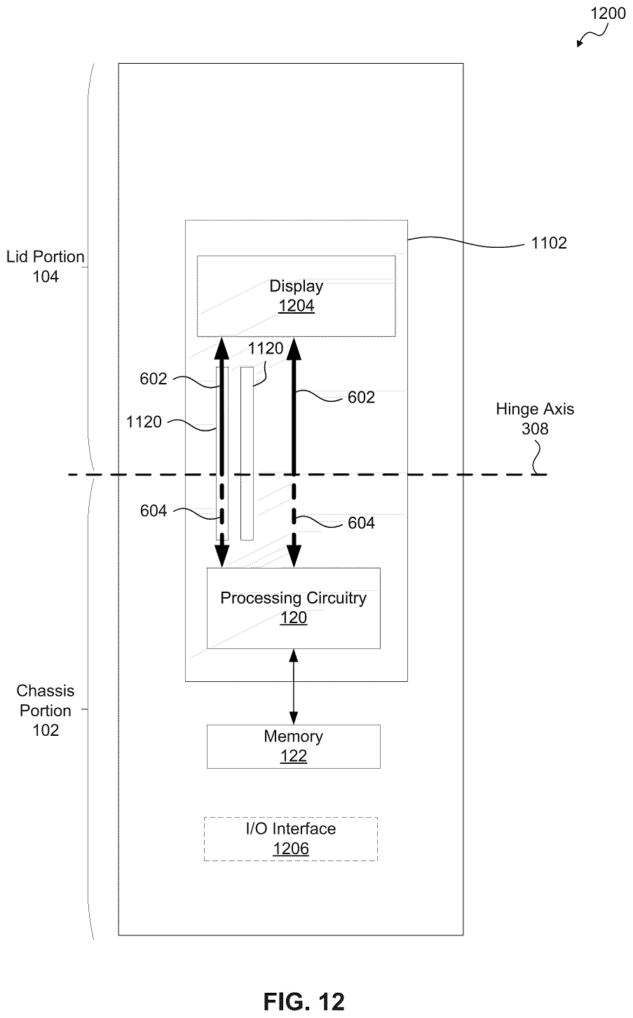

FIG. 12 illustrates a schematic view of a foldable electronic device 1200 according to the disclosure. The electronic device 1200 may be similar to electronic devices 100, 200, and/or 1100, and foldable about axis 308. In this example, the electronic device 1200 includes a thermal conductor 1102 having two slits 1120. The electronic device 1200 may also include interconnects 602. In this example, the device 1200 includes two interconnects 602, with one of the interconnects 602 being accommodated (at least partially) within a slit 1120 within the thermal conductor 1102. Additionally, or alternatively, the lid portion 104 may include one or more input/output interfaces, such as display 1204. Additionally, or alternatively, the lid portion 104 may include circuitry, other input/output interface(s), memory, and/or processor(s) (e.g., processing circuitry), which may be couplable to the interconnect(s) 602 and/or thermal conductor(s) 1102 the display 1204. The processing circuitry 1202 is further coupled to component(s) of the base 102 (e.g., processing circuitry 120). The base 102 may further include one or more input/output (I/O) interfaces 1206, such as a keyboard, and/or other circiutry.

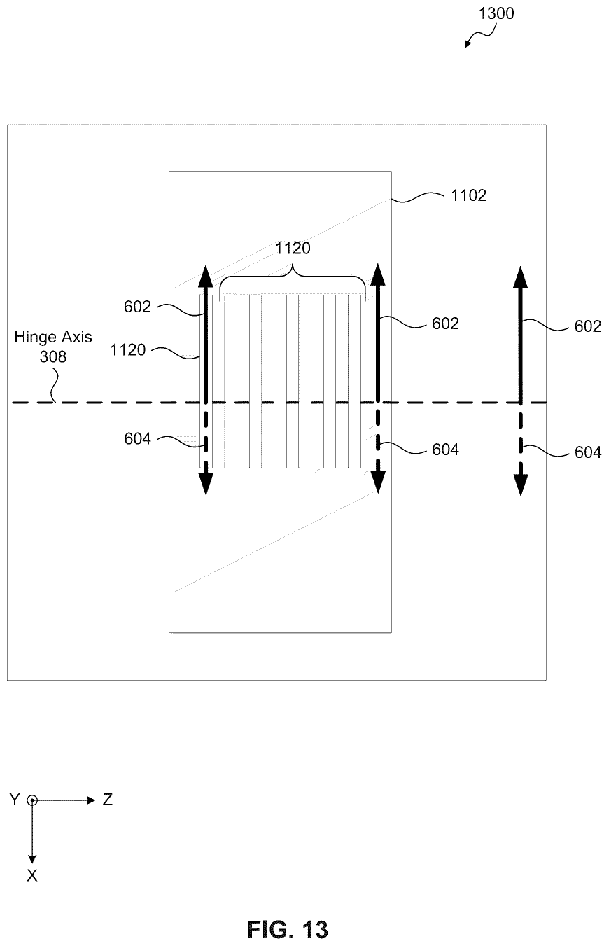

FIG. 13 illustrates a schematic view of a foldable electronic device 1300 according to the disclosure. The electronic device 1300 may be similar to electronic devices 100, 200, 1100 and/or 1200. In this example, the electronic device 1300 includes thermal conductor 1102 having several slits 1120. Here, one or more interconnects 602 may be accommodated in a slit 1102, may be outside of a slit 1102 but overlapping the thermal conductor 1102, and/or outside of the thermal conductor 1102 so as to not overlap.

The electronic device(s) 100, 200, 1100, 1200, and/or 1300 may be identified with any suitable type of device as discussed herein, and which may include one or more interconnects between two different portions of the electronic device. The electronic device(s) may be identified with any suitable device having at least two different portions that are at least partially rotatable with respect to one another. Thus, the electronic device(s) may be identified with a wireless device, a user equipment (UE), a mobile phone, a laptop computer, a tablet, a wearable device, etc.

The electronics device(s) may comprise processing circuitry, which may be configured as any suitable number and/or type of computer processors, and which may function to control the electronic device(s) and/or other components of the electronic device(s). The processing circuitry may be identified with one or more processors (or suitable portions thereof) implemented by the electronic device(s). The processing circuitry may be identified with one or more processors such as a host processor, a digital signal processor, one or more microprocessors, graphics processors, baseband processors, microcontrollers, an application-specific integrated circuit (ASIC), part (or the entirety of) a field-programmable gate array (FPGA), etc.

In any event, the processing circuitry may be configured to carry out instructions to perform arithmetical, logical, and/or input/output (I/O) operations, and/or to control the operation of one or more components of electronic device to perform various functions as described herein. The processing circuitry may include one or more microprocessor cores, memory registers, buffers, clocks, etc., and may generate electronic control signals associated with the components of the device(s) to control and/or modify the operation of these components. The processing circuitry may communicate with and/or control functions associated with the memory, as well as any other components of the electronic device(s).

The memory stores data and/or instructions such that, when executed by the processing circuitry, cause the electronic device(s) to perform various functions such as controlling, monitoring, and/or regulating the operation of the electronic device(s), providing data to be transmitted and/or received via the interconnect(s), and/or processing signals that are received via the interconnect(s) as discussed herein. The memory may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc. The memory may be non-removable, removable, or a combination of both. The memory may be implemented as a non-transitory computer readable medium storing one or more executable instructions such as, for example, logic, algorithms, code, etc. The instructions, logic, code, etc., stored in the memory may include an operating system (OS) which may enable the functionality disclosed herein to be functionally realized.

### EXAMPLES

The following examples pertain to various techniques of the present disclosure.

An example (e.g. example 1) is a component of an electronic device, comprising: a hinge portion rotatably coupling the component to another component, the hinge portion having an axis of which the component is rotatable with respect to the other component; and a housing comprising a conductor, the housing having an opening passable by the conductor, wherein the opening is coincident to the axis.

Another example (e.g. example 2) relates to a previously-described example (e.g. example 1), wherein the housing further comprises a fixed portion of the conductor, a free portion of the conductor extending out of the opening.

Another example (e.g. example 3) relates to a previously-described example (e.g. example 2), wherein the free portion extends from the opening in a radial direction of the axis.

Another example (e.g. example 4) relates to a previously-described example (e.g. one or more of examples 1-3), wherein the housing further comprises a routing path that terminates at the opening coincident to the axis, wherein the routing path comprises the conductor.

Another example (e.g. example 5) relates to a previously-described example (e.g. one or more of examples 1-4), wherein the conductor communicatively couples the component to the other component.

Another example (e.g. example 6) relates to a previously-described example (e.g. one or more of examples 1-5), wherein the conductor is a flexible conductor.

Another example (e.g. example 7) relates to a previously-described example (e.g. one or more of examples 1-6), wherein the conductor is a flexible flat cable (FFC).

Another example (e.g. example 8) relates to a previously-described example (e.g. one or more of examples 1-7), wherein the housing further comprises a heat spreader to conduct heat between the component and the other component.

Another example (e.g. example 9) relates to a previously-described example (e.g. example 8), wherein the heat spreader comprises one or more elongated slits extending perpendicular to the axis and configured to increase a flexibility of the heat spreader at least at the axis, the conductor being at least partially within a slit of the one or more elongated slits.

Another example (e.g. example 10) relates to a previously-described example (e.g. one or more of examples 1-9), wherein the conductor comprises a heat spreader to conduct heat between the component and the other component.

Another example (e.g. example 11) relates to a previously-described example (e.g. example 1-10), wherein the heat spreader comprises one or more elongated slits extending in a direction passable by the conductor via the opening, the one or more elongated slits increasing a flexibility of the heat spreader at least at the axis.

Another example (e.g. example 12) relates to a previously-described example (e.g. one or more of examples 8-11), wherein the heat spreader comprises a graphite sheet.

Another example (e.g. example 13) relates to a previously-described example (e.g. one or more of examples 1-12), wherein the component is a lid and the other component is a base of the electronic device.

Another example (e.g. example 14) relates to a previously-described example (e.g. one or more of examples 1-12), wherein the component is a base and the other component is a lid of the electronic device.

Another example (e.g. example 15) relates to a device comprising the component of any of examples 1-14.

Another example (e.g. example 16) relates to an electronic device, comprising: first and second portions; a hinge rotatably coupling the first portion to the second portion, the first portion being rotatable about an axis of the hinge with respect to the second portion; and a conductor extending between the first and the second portions, the conductor including a fixed portion and a free portion, the fixed portion of the conductor being fixed to the first portion of the electronic device and the free portion of the conductor being free from the first portion of the electronic device, wherein a delineation between the fixed and free portions of the conductor is coincident with the axis.

Another example (e.g. example 17) relates to a previously-described example (e.g. example 16), wherein the fixed portion extends radially inward to the axis and the free portion extends radially outward from the axis.

Another example (e.g. example 18) relates to a previously-described example (e.g. one or more of examples 16-17), wherein the conductor communicatively couples the first and second portions together.

Another example (e.g. example 19) relates to a previously-described example (e.g. one or more of examples 16-18), wherein the conductor is a flexible conductor.

Another example (e.g. example 20) relates to a previously-described example (e.g. one or more of examples 16-19), further comprising a heat spreader to conduct heat between the first portion and the second portion, the heat spreader including a fixed portion and a free portion, the fixed portion of the heat spreader being fixed to the first portion of the electronic device and the free portion of the heat spreader being free from the first portion of the electronic device, wherein a delineation between the fixed and free portions of the heat spreader is coincident with the axis.

Another example (e.g. example 20) relates to a previously-described example (e.g. example 20), wherein the heat spreader comprises one or more elongated slits extending perpendicular to the axis, the one or more elongated slits being configured to increase a flexibility of the heat spreader at least at the axis.

Another example (e.g. example 22) relates to a previously-described example (e.g. example 21), wherein a slit of the one or more elongated slits comprises the conductor.

Another example (e.g. example 23) relates to a previously-described example (e.g. one or more of examples 16-17), wherein the conductor is a heat spreader configured to thermally couple the first and second portions together.

Another example (e.g. example 24) relates to a previously-described example (e.g. example 23), wherein the heat spreader comprises one or more elongated slits extending perpendicular to the axis, the one or more elongated slits being configured to increase a flexibility of the heat spreader at least at the axis.

Another example (e.g. example 25) relates to an electronic device, comprising: a base and a lid; a hinge configured to rotatably couple the lid to the base, the lid being rotatable about a hinge axis of the hinge with respect to the base; and a conductor extending between the lid and the base, the conductor including a fixed portion and a free portion, a delineation between the fixed and the free portions of the conductor is coincident with the hinge axis, wherein: the fixed portion of the conductor being fixed to the lid and the free portion of the conductor being free from the lid, or the fixed portion of the conductor being fixed to the base and the free portion of the conductor being free from the base.

Another example (e.g. example 26) relates to a component of an electronic device, comprising: hinging means for rotatably coupling the component to another component, the hinging means having an axis of which the component is rotatable with respect to the other component; and housing means for housing conducting means, the housing means having an opening passable by the conducting means, wherein the opening is coincident to the axis.

Another example (e.g. example 27) relates to a previously-described example (e.g. example 26), wherein the housing means further comprises a fixed portion of the conducting means, a free portion of the conductor extending out of the opening.

Another example (e.g. example 28) relates to a previously-described example (e.g. example 27), wherein the free portion extends from the opening in a radial direction of the axis.

Another example (e.g. example 29) relates to a previously-described example (e.g. one or more of examples 26-28), wherein the housing means further comprises a routing path that terminates at the opening coincident to the axis, wherein the routing path comprises the conducting means.

Another example (e.g. example 30) relates to a previously-described example (e.g. one or more of examples 26-29), wherein the conducting means is for communicatively coupling the component to the other component.

Another example (e.g. example 31) relates to a previously-described example (e.g. one or more of examples 26-30), wherein the conducting means is a flexible conductor.

Another example (e.g. example 32) relates to a previously-described example (e.g. one or more of examples 26-31), wherein the conducting means is a flexible flat cable (FFC).

Another example (e.g. example 33) relates to a previously-described example (e.g. one or more of examples 26-32), wherein the housing means further comprises heat spreading means for conducting heat between the component and the other component.

Another example (e.g. example 34) relates to a previously-described example (e.g. example 33), wherein the heat spreading means comprises one or more elongated slits extending perpendicular to the axis and configured to increase a flexibility of the heat spreading means at least at the axis, the conducting means being at least partially within a slit of the one or more elongated slits.

Another example (e.g. example 35) relates to a previously-described example (e.g. one or more of examples 26-34), wherein the conducting means comprises heat spreading means for conducting heat between the component and the other component.

Another example (e.g. example 36) relates to a previously-described example (e.g. example 35), wherein the heat spreading means comprises one or more elongated slits extending in a direction passable by the conductor via the opening, the one or more elongated slits increasing a flexibility of the heat spreading means at least at the axis.

Another example (e.g. example 37) relates to a previously-described example (e.g. one or more of examples 33-36), wherein the heat spreading means comprises a graphite sheet.

Another example (e.g. example 38) relates to a previously-described example (e.g. one or more of examples 26-37), wherein the component is a lid and the other component is a base of the electronic device.

Another example (e.g. example 39) relates to a previously-described example (e.g. one or more of examples 26-37), wherein the component is a base and the other component is a lid of the electronic device.

Another example (e.g. example 40) relates to a device comprising the component of any of examples 26-39.

Another example (e.g. example 41) relates to an electronic device, comprising: first and second portions; hinging means for rotatably coupling the first portion to the second portion, the first portion being rotatable about an axis of the hinging means with respect to the second portion; and conducting means extending between the first and the second portions, the conducting means including a fixed portion and a free portion, the fixed portion of the conducting means being fixed to the first portion of the electronic device and the free portion of the conducting means being free from the first portion of the electronic device, wherein a delineation between the fixed and free portions of the conducting means is coincident with the axis.

Another example (e.g. example 42) relates to a previously-described example (e.g. example 41), wherein the fixed portion extends radially inward to the axis and the free portion extends radially outward from the axis.

Another example (e.g. example 43) relates to a previously-described example (e.g. one or more of examples 41-42), wherein the conducting means is for communicatively coupling the first and second portions together.

Another example (e.g. example 44) relates to a previously-described example (e.g. one or more of examples 41-43), wherein the conducting means is a flexible conductor.

Another example (e.g. example 45) relates to a previously-described example (e.g. one or more of examples 41-44), further comprising heat spreading means for conducting heat between the first portion and the second portion, the heat spreading means including a fixed portion and a free portion, the fixed portion of the heat spreading means being fixed to the first portion of the electronic device and the free portion of the heat spreading means being free from the first portion of the electronic device, wherein a delineation between the fixed and free portions of the heat spreading means is coincident with the axis.

Another example (e.g. example 46) relates to a previously-described example (e.g. example 46),

Another example (e.g. example 46) relates to a previously-described example (e.g. example 45), wherein the heat spreading means comprises one or more elongated slits extending perpendicular to the axis, the one or more elongated slits being configured to increase a flexibility of the heat spreading means at least at the axis.

Another example (e.g. example 47) relates to a previously-described example (e.g. example 46), wherein a slit of the one or more elongated slits comprises the conducting means.

Another example (e.g. example 48) relates to a previously-described example (e.g. one or more of examples 41-42), wherein the conducting means is a heat spreading means for thermally coupling the first and second portions together.

Another example (e.g. example 49) relates to a previously-described example (e.g. example 48), wherein the heat spreading means comprises one or more elongated slits extending perpendicular to the axis, the one or more elongated slits being configured to increase a flexibility of the heat spreading means at least at the axis.

Another example (e.g. example 50) relates to an electronic device, comprising: a base and a lid; hinging means for rotatably coupling the lid to the base, the lid being rotatable about a hinge axis of the hinging means with respect to the base; and conducting means extending between the lid and the base, the conducting means including a fixed portion and a free portion, a delineation between the fixed and the free portions of the conducting means is coincident with the hinge axis, wherein: the fixed portion of the conducting means being fixed to the lid and the free portion of the conducting means being free from the lid, or the fixed portion of the conducting means being fixed to the base and the free portion of the conducting means being free from the base.

Another example (e.g. example 51) relates to an apparatus as shown and described.

Another example (e.g. example 52) relates to a method as shown and described.

### Conclusion

The aforementioned description will so fully reveal the general nature of the implementation of the disclosure that others can, by applying knowledge within the skill of the art, readily modify and/or adapt for various applications such specific implementations without undue experimentation and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Each implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The exemplary implementations described herein are provided for illustrative purposes, and are not limiting. Other implementations are possible, and modifications may be made to the exemplary implementations. Therefore, the specification is not meant to limit the disclosure. Rather, the scope of the disclosure is defined only in accordance with the following claims and their equivalents.

Throughout the drawings, it should be noted that like reference numbers are used to depict the same or similar elements, features, and structures, unless otherwise noted.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The phrase “at least one of” with regard to a group of elements may be used herein to mean at least one element from the group consisting of the elements. The phrase “at least one of” with regard to a group of elements may be used herein to mean a selection of: one of the listed elements, a plurality of one of the listed elements, a plurality of individual listed elements, or a plurality of a multiple of individual listed elements.

1. A component of an electronic device, comprising:
a hinge portion rotatably coupling the component to another component, the hinge portion having an axis of which the component is rotatable with respect to the other component; and
a housing comprising a conductor, the housing having an opening passable by the conductor, wherein the opening is coincident to the axis.

2. The component of claim 1, wherein the housing further comprises a fixed portion of the conductor, a free portion of the conductor extending out of the opening.

3. The component of claim 2, wherein the free portion extends from the opening in a radial direction of the axis.

4. The component of claim 1, wherein the housing further comprises a routing path that terminates at the opening coincident to the axis, wherein the routing path comprises the conductor.

5. The component of claim 1, wherein the conductor communicatively couples the component to the other component.

6. The component of claim 1, wherein the conductor is a flexible flat cable (FFC).

7. The component of claim 1, wherein the housing further comprises a heat spreader to conduct heat between the component and the other component.

8. The component of claim 7, wherein the heat spreader comprises one or more elongated slits extending perpendicular to the axis and configured to increase a flexibility of the heat spreader at the axis, the conductor being at least partially within a slit of the one or more elongated slits.

9. The component of claim 1, wherein the conductor comprises a heat spreader to conduct heat between the component and the other component.

10. The component of claim 9, wherein the heat spreader comprises one or more elongated slits extending in a direction passable by the conductor via the opening, the one or more elongated slits increasing a flexibility of the heat spreader at the axis.

11. The component of claim 1, wherein the component is a lid and the other component is a base of the electronic device.

12. An electronic device, comprising:
first and second portions;
a hinge rotatably coupling the first portion to the second portion, the first portion being rotatable about an axis of the hinge with respect to the second portion; and
a conductor extending between the first and the second portions, the conductor including a fixed portion and a free portion, the fixed portion of the conductor being fixed to the first portion of the electronic device and the free portion of the conductor being free from the first portion of the electronic device, wherein a delineation between the fixed and free portions of the conductor is coincident with the axis.

13. The electronic device of claim 12, wherein the fixed portion extends radially inward to the hinge axis and the free portion extends radially outward from the hinge axis.

14. The electronic device of claim 12, wherein the conductor communicatively couples the first and second portions together.

15. The electronic device of claim 12, wherein the conductor is a flexible conductor.

16. The electronic device of claim 12, further comprising a heat spreader to conduct heat between the first portion and the second portion, the heat spreader including a fixed portion and a free portion, the fixed portion of the heat spreader being fixed to the first portion of the electronic device and the free portion of the heat spreader being free from the first portion of the electronic device, wherein a delineation between the fixed and free portions of the heat spreader is coincident with the hinge axis.

17. The electronic device of claim 16, wherein the heat spreader comprises one or more elongated slits extending perpendicular to the hinge axis, the one or more elongated slits being configured to increase a flexibility of the heat spreader at the hinge axis.

18. The electronic device of claim 17, wherein a slit of the one or more elongated slits comprises the conductor.

19. The electronic device of claim 12, wherein the conductor is a heat spreader configured to thermally couple the first and second portions together.

20. An electronic device, comprising:
a base and a lid;
a hinge configured to rotatably couple the lid to the base, the lid being rotatable about a hinge axis of the hinge with respect to the base; and
a conductor extending between the lid and the base, the conductor including a fixed portion and a free portion, a delineation between the fixed and the free portions of the conductor is coincident with the hinge axis, wherein: the fixed portion of the conductor being fixed to the lid and the free portion of the conductor being free from the lid, or the fixed portion of the conductor being fixed to the base and the free portion of the conductor being free from the base.
